(19) United States
(12) Patent Application Publication
(10) Pub. No.: US 2017/0338290 A1
(43) Pub. Date: Nov. 23, 2017

(54) WOLED DISPLAY DEVICE

(71) Applicant: Shenzhen China Star Optoelectronics Technology Co. Ltd., Shenzhen City (CN)

(72) Inventors: Hong Liu, Shenzhen City (CN); Yungjui Lee, Shenzhen City (CN); Hsiaohsien Chen, Shenzhen City (CN)

(21) Appl. No.: 15/120,744

(22) PCT Filed: Jun. 15, 2016
(86) PCT No.: PCT/CN2016/085799

§ 371 Date: Aug. 23, 2016

(30) Foreign Application Priority Data
May 23, 2016 (CN) 201610345123.8

(51) Int. Cl. H01L 27/32; H01L 51/52

(52) U.S. Cl. CPC H01L 27/3213; H01L 51/5237; H01L 27/322; H01L 27/3248

(57) ABSTRACT

Disclosed is a WOLED display device, including a substrate (10), a TFT array layer (20) located on the substrate (10), a light purification layer (60) located on the TFT array layer (20), a color filter layer (40) located on the light purification layer (60) and a WOLED (30) located on the color filter layer (40). The color filter layer (40) includes red, green, blue light resist units (41, 42, 43) which are aligned in array. The red, green, blue light resist units (41, 42, 43) filtrate white light to respectively form red, green, blue light, and the light purification layer (60) selectively absorbs the red, green, blue light to decrease half band widths thereof to promote the light filtering effect of the color filter layer (40), and light purity of the three primary colors of red, green, and blue are high to show a wider color gamut.

### FIELD OF THE INVENTION

The present invention relates to a flat panel display field, and more particularly to a WOLED display device.

### BACKGROUND OF THE INVENTION

The active matrix panel display elements possess many merits of thin frame, power saving, no radiation, etc. and have been widely used. The Organic Light Emitting Diode (OLED) display technology is a flat panel display technology which has great prospects for development. It possesses extremely excellent display performance, and particularly the properties of self-illumination, simple structure, ultra thin, fast response speed, wide view angle, low power consumption and capability of realizing flexible display, and therefore is considered as the “dream display”. Meanwhile, the investment for the production equipments is far smaller than the Thin Film Transistor-Liquid Crystal Display (TFT-LCD). It has been favored by respective big display makers and has become the main selection of the third generation display element of the display technology field. At present, the OLED has reached the point before mass production. With the further research and development, the new technologies constantly appear, and someday, there will be a breakthrough for the development of the OLED display elements.

For realizing the full color of the OLED display device, one way is to achieve it by laminating the White Organic Light Emitting Diode (WOLED) and the Color Filter (CF). The lamination structure of the WOLED and CF does not require accurate mask process to achieve the high resolution of the OLED display device, which is the one that has been widely applied.

FIG. 1 is a structure diagram of a red sub pixel region of a WOLED display device utilizing the aforesaid structure; the device comprises a substrate 100, a TFT structure 200 located on the substrate 100, a first passivation layer 300 covering the TFT structure 200, a red color resist layer 410 located on the first passivation layer 300, a second passivation layer 500 being located on the first passivation layer 300 and covering the red color resist layer 410 and a WOLED 600 located on the second passivation layer 500 and driven by the TFT structure 200. The structures of the green sub pixel region and the blue sub pixel region on the WOLED display device are the same as that of the red sub pixel region. The white light emitting layer of the WOLED is formed by red, green, blue emitting fluorescent materials mixed evaporation. The red, green, blue color resist layers of the color filter cannot better filtrate the white light emitted by the white light emitting layer. As shown in FIG. 2, which is a spectrum diagram of white light emitted by an illustrated WOLED, there are certain peaks in the two positions which are indicated with circles (between 480 nm and 530 nm, between 530 nm and 580 nm). The existence of the peaks makes that the effects of and blue light and the green light are poor after the white light source emitted by the WOLED passes through the color filter layer. Particularly, after the white light passes through the blue color resist layer, the half band width of the blue light is wider in general, and the purity of the blue light is lower. As shown in FIG. 3, which is a spectrum diagram that the red, green, blue light resist layers in the color filter layer respectively filtrated white light emitted by the WOLED in an illustrated WOLED display device. The small protrusion in figure indicated with circle (between 480 nm and 530 nm) will influence the purity of the blue light. Therefore, the WOLED display device has drawbacks that the lighting purities of the red, green, blue, three primary colors are relatively low, and the color gamut is narrow.

### SUMMARY OF THE INVENTION

An objective of the present invention is to provide a WOLED display device, in which a light purification layer with a specific absorption wavelength is provided to raise the light filtering effect of the color filter layer, and the light purities of the red, green, blue, three primary colors are high to show a wider color gamut.

For realizing the aforesaid objective, the present invention provides a WOLED display device, comprising a substrate, a TFT array layer located on the substrate, a light purification layer located on the TFT array layer, a color filter layer located on the light purification layer and a WOLED located on the color filter layer; wherein

the color filter layer comprises a plurality of red, green, blue light resist units which are aligned in array;

the red, green, blue light resist units of the color filter layer filtrate white light emitted by the WOLED to respectively form red, green, blue lights, and the light purification layer selectively absorbs the red, green, blue lights to decrease half band widths of the red, green, blue lights to raise purities thereof.

The light purification layer has an absorption peak of 500 nm in a visible spectrum for visible light, and has no absorption peak in the visible spectrum for other bands of the visible light.

The light purification layer has an absorption peak of 576 nm in a visible spectrum for visible light, and has no absorption peak in the visible spectrum for other bands of the visible light.

The light purification layer has absorption peaks of 500 nm and 576 nm in a visible spectrum for visible light, and has no absorption peak in the visible spectrum for other bands of the visible light.

The light purification layer is a dye film.

The WOLED comprises an anode, a white light emitting layer and a cathode which stack up from bottom to top.

The white light emitting layer is formed by red, green, blue emitting fluorescent materials mixed evaporation.

The TFT array layer comprises a plurality of TFT units which are aligned in array; the TFT unit comprises a first gate and a second gate formed on the substrate, a gate insulation layer formed on the first gate and the second gate, a first active layer and a second active layer formed on the gate insulation layer, a first source and a first drain formed on the first active layer and a second source and a second drain formed on the second active layer, and the first drain is coupled to the second gate, and the first gate, the gate insulation layer, the first active layer, the first source and the first drain construct a switch thin film transistor, and the second gate, the gate insulation layer, the second active layer, the second source and the second drain construct a drive thin film transistor;

the anode of the WOLED is coupled to the second drain of the drive thin film transistor.

The WOLED display device further comprises a first passivation layer located between the TFT array layer and the light purification layer, and a second passivation layer located between the color filter layer and the WOLED;

the first passivation layer and the second passivation layer comprises vias correspondingly above the second drain of the drive thin film transistor, and the anode of the WOLED is coupled to the second drain of the drive thin film transistor through the vias.

Material of the anode is ITO.

The present invention further provides a WOLED display device, comprising a substrate, a TFT array layer located on the substrate, a light purification layer located on the TFT array layer, a color filter layer located on the light purification layer and a WOLED located on the color filter layer; wherein

the color filter layer comprises a plurality of red, green, blue light resist units which are aligned in array;

the red, green, blue light resist units of the color filter layer filtrate white light emitted by the WOLED to respectively form red, green, blue lights, and the light purification layer selectively absorbs the red, green, blue lights to decrease half band widths of the red, green, blue lights to raise purities thereof;

wherein the light purification layer is a dye film;

wherein the WOLED comprises an anode, a white light emitting layer and a cathode which stack up from bottom to top;

wherein material of the anode is ITO;

wherein the white light emitting layer is formed by red, green, blue emitting fluorescent materials mixed evaporation.

The benefits of the present invention are: the present invention provides a WOLED display device, comprising a substrate, a TFT array layer located on the substrate, a light purification layer located on the TFT array layer, a color filter layer located on the light purification layer and a WOLED located on the color filter layer; wherein the red, green, blue light resist units of the color filter layer filtrate white light emitted by the WOLED to respectively form red, green, blue lights, and the light purification layer selectively absorbs the red, green, blue lights to decrease half band widths of the red, green, blue lights to promote the light filtering effect of the color filter layer, and the light purities of the red, green, blue, three primary colors are high to show a wider color gamut.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a structure diagram of a red sub pixel region of a WOLED display device according to prior art;

FIG. 2 is a spectrum diagram of white light emitted by the WOLED in an illustrated WOLED display device;

FIG. 3 is a spectrum diagram that the red, green, blue light resist layers in the color filter layer respectively filtrated white light emitted by the WOLED in an illustrated WOLED display device;

FIG. 4 is a structure diagram of the WOLED display device according to the present invention.

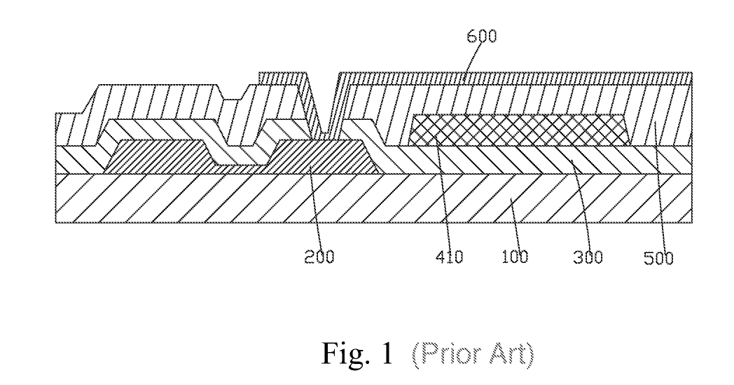

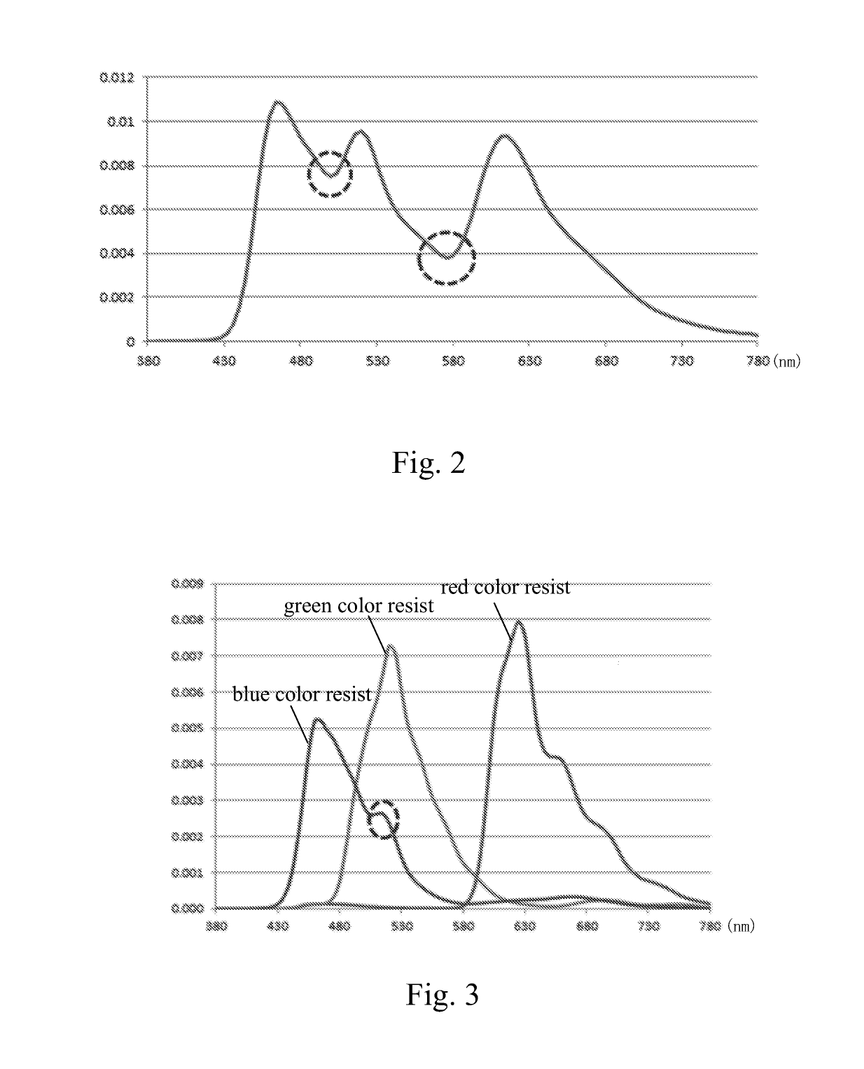

### DETAILED DESCRIPTION OF PREFERRED EMBODIMENTS

For better explaining the technical solution and the effect of the present invention, the present invention will be further described in detail with the accompanying drawings and the specific embodiments.

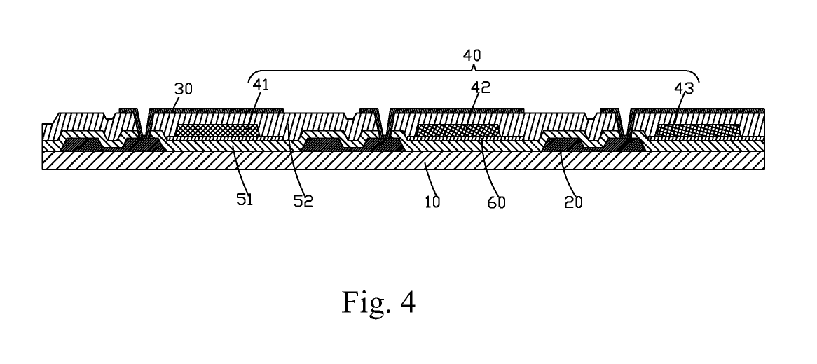

Please refer to FIG. 4. The present invention provides a WOLED display device, comprising a substrate 10, a TFT array layer 20 located on the substrate 10, a light purification layer 60 located on the TFT array layer 20, a color filter layer 40 located on the light purification layer 60 and a WOLED 30 located on the color filter layer 40.

Specifically, the color filter layer 40 comprises a plurality of red, green, blue light resist units 41, 42, 43 which are aligned in array.

Specifically, the red, green, blue light resist units 41, 42, 43 of the color filter layer 40 filtrate white light emitted by the WOLED 30 to respectively form red, green, blue lights, and the light purification layer 60 selectively absorbs the red, green, blue lights to decrease half band widths of the red, green, blue lights to make the WOLED display device emit the red, green, blue lights with higher purities, and thus to shows a wider color gamut.

Specifically, the light purification layer 60 has an absorption peak of 500 nm in a visible spectrum for visible light, and has no absorption peak in the visible spectrum for other bands of the visible light. The transmission ratio for the other bands of the visible light is nearly equal to 100%, and can narrow the half band width of the blue light to raise the purity of the blue light.

Or, the light purification layer 60 has an absorption peak of 576 nm in a visible spectrum for visible light, and has no absorption peak in the visible spectrum for other bands of the visible light. The transmission ratio for the other bands of the visible light is nearly equal to 100%, and can narrow the half band width of the green light to raise the purity of the green light.

Or, the light purification layer 60 has absorption peaks of 500 nm and 576 nm in a visible spectrum for visible light at the same time, and has no absorption peak in the visible spectrum for other bands of the visible light. The transmission ratio for the other bands of the visible light is nearly equal to 100%, and can narrow the half band widths of the blue light and green light to raise the purities of the blue light and the green light.

Specifically, the light purification layer 60 is a dye film or the other material film layer having a specific absorption wavelength.

Specifically, the WOLED 30 comprises an anode, a white light emitting layer and a cathode which stack up from bottom to top.

Specifically, the white light emitting layer is formed by red, green, blue emitting fluorescent materials mixed evaporation.

Specifically, the TFT array layer 20 comprises a plurality of TFT units which are aligned in array; the TFT unit comprises a first gate and a second gate formed on the substrate 10, a gate insulation layer formed on the first gate and the second gate, a first active layer and a second active layer formed on the gate insulation layer, a first source and a first drain formed on the first active layer and a second source and a second drain formed on the second active layer, and the first drain is coupled to the second gate, and the first gate, the gate insulation layer, the first active layer, the first source and the first drain construct a switch thin film transistor, and the second gate, the gate insulation layer, the second active layer, the second source and the second drain construct a drive thin film transistor; the anode of the WOLED 30 is coupled to the second drain of the drive thin film transistor.

Specifically, the WOLED display device further comprises a first passivation layer 51 located between the TFT array layer 20 and the light purification layer 60, and a second passivation layer 52 located between the color filter layer 40 and the WOLED 30.

Specifically, the first passivation layer 51 and the second passivation layer 52 comprises vias correspondingly above the second drain of the drive thin film transistor, and the anode of the WOLED 30 is coupled to the second drain of the drive thin film transistor through the vias.

Specifically, material of the anode is ITO.

In conclusion, the present invention provides a WOLED display device, comprising a substrate, a TFT array layer located on the substrate, a light purification layer located on the TFT array layer, a color filter layer located on the light purification layer and a WOLED located on the color filter layer; wherein the red, green, blue light resist units of the color filter layer filtrate white light emitted by the WOLED to respectively form red, green, blue lights, and the light purification layer selectively absorbs the red, green, blue lights to decrease half band widths of the red, green, blue lights to promote the light filtering effect of the color filter layer, and the light purities of the red, green, blue, three primary colors are high to show a wider color gamut.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

1: A white organic light-emitting diode (WOLED) display device, comprising a substrate, a thin-film transistor (TFT) array layer located on the substrate, a light purification layer located on the TFT array layer, a color filter layer located on the light purification layer and a WOLED located on the color filter layer; wherein
the color filter layer comprises a plurality of red, green, blue light resist units which are aligned in an array;
the red, green, blue light resist units of the color filter layer filtrate white light emitting from the WOLED to respectively form red, green, blue light, and the light purification layer selectively absorbs the red, green, blue light so as to decrease half band widths of the red, green, blue light and improve purity thereof;
wherein the red, green, and blue light resist units of color filter layer are directly formed on the light purification layer such that the red, green, and blue light from the red, green, and blue light resist units directly transmits through the light purification layer to be selectively and directly absorbed thereby.

2: The WOLED display device according to claim 1, wherein the light purification layer has an absorption peak of 500 nm in a visible spectrum for visible light, and has no absorption peak in the visible spectrum for other bands of the visible light.

3: The WOLED display device according to claim 1, wherein the light purification layer has an absorption peak of 576 nm in a visible spectrum for visible light, and has no absorption peak in the visible spectrum for other bands of the visible light.

4: The WOLED display device according to claim 1, wherein the light purification layer has absorption peaks of 500 nm and 576 nm in a visible spectrum for visible light, and has no absorption peak in the visible spectrum for other bands of the visible light.

5: The WOLED display device according to claim 1, wherein the light purification layer is a dye film.

6: The WOLED display device according to claim 1, wherein the WOLED comprises an anode, a white light emitting layer and a cathode which stack up from bottom to top.

7: The WOLED display device according to claim 6, wherein the white light emitting layer is formed by blending red, green, blue emitting fluorescent materials through evaporation thereof.

8: The WOLED display device according to claim 6, wherein the TFT array layer comprises a plurality of TFT units which are aligned in array; the TFT unit comprises a first gate and a second gate formed on the substrate, a gate insulation layer formed on the first gate and the second gate, a first active layer and a second active layer formed on the gate insulation layer, a first source and a first drain formed on the first active layer and a second source and a second drain formed on the second active layer, and the first drain is coupled to the second gate, and the first gate, the gate insulation layer, the first active layer, the first source and the first drain construct a switch thin film transistor, and the second gate, the gate insulation layer, the second active layer, the second source and the second drain construct a drive thin film transistor;
the anode of the WOLED is coupled to the second drain of the drive thin film transistor.

9: The WOLED display device according to claim 8, further comprising a first passivation layer located between the TFT array layer and the light purification layer, and a second passivation layer located between the color filter layer and the WOLED;
the first passivation layer and the second passivation layer comprise vias corresponding to and located above the second drain of the drive thin film transistor, and the anode of the WOLED is coupled to the second drain of the drive thin film transistor through the vias.

10: The WOLED display device according to claim 6, wherein a material of the anode is indium tin oxide (ITO).

11: A white organic light-emitting diode (WOLED) display device, comprising a substrate, a thin-film transistor (TFT) array layer located on the substrate, a light purification layer located on the TFT array layer, a color filter layer located on the light purification layer and a WOLED located on the color filter layer; wherein
the color filter layer comprises a plurality of red, green, blue light resist units which are aligned in an array;
the red, green, blue light resist units of the color filter layer filtrate white light emitting from the WOLED to respectively form red, green, blue light, and the light purification layer selectively absorbs the red, green, blue light so as to decrease half band widths of the red, green, blue light and improve purity thereof;
wherein the red, green, and blue light resist units of color filter layer are directly formed on the light purification layer such that the red, green, and blue light from the red, green, and blue light resist units directly transmits through the light purification layer to be selectively and directly absorbed thereby;
wherein the light purification layer is a dye film;
wherein the WOLED comprises an anode, a white light emitting layer and a cathode which stack up from bottom to top;
wherein a material of the anode is indium tin oxide (ITO); and
wherein the white light emitting layer is formed by blending red, green, blue emitting fluorescent materials through evaporation thereof.

12: The WOLED display device according to claim 11, wherein the light purification layer has an absorption peak of 500 nm in a visible spectrum for visible light, and has no absorption peak in the visible spectrum for other bands of the visible light.

13: The WOLED display device according to claim 11, wherein the light purification layer has an absorption peak of 576 nm in a visible spectrum for visible light, and has no absorption peak in the visible spectrum for other bands of the visible light.

14: The WOLED display device according to claim 11, wherein the light purification layer has absorption peaks of 500 nm and 576 nm in a visible spectrum for visible light, and has no absorption peak in the visible spectrum for other bands of the visible light.

15: The WOLED display device according to claim 11, wherein the TFT array layer comprises a plurality of TFT units which are aligned in array; the TFT unit comprises a first gate and a second gate formed on the substrate, a gate insulation layer formed on the first gate and the second gate, a first active layer and a second active layer formed on the gate insulation layer, a first source and a first drain formed on the first active layer and a second source and a second drain formed on the second active layer, and the first drain is coupled to the second gate, and the first gate, the gate insulation layer, the first active layer, the first source and the first drain construct a switch thin film transistor, and the second gate, the gate insulation layer, the second active layer, the second source and the second drain construct a drive thin film transistor;
the anode of the WOLED is coupled to the second drain of the drive thin film transistor.

16: The WOLED display device according to claim 15, further comprising a first passivation layer located between the TFT array layer and the light purification layer, and a second passivation layer located between the color filter layer and the WOLED;
the first passivation layer and the second passivation layer c comprise vias corresponding to and located above the second drain of the drive thin film transistor, and the anode of the WOLED is coupled to the second drain of the drive thin film transistor through the vias.
